(19) United States
(12) Patent Application Publication
(10) Pub. No.: US 2021/0004678 A1
(43) Pub. Date: Jan. 7, 2021

(54) NEURAL CIRCUIT

(71) Applicant: Industrial Technology Research Institute, Hsinchu (TW)

(72) Inventors: Shih-Chieh Chang, Hsinchu City (TW); Sih-Han Li, New Taipei City (TW); Shyh-Shyuan Sheu, Hsinchu County (TW); Jian-Wei Su, Hsinchu City (TW); Heng-Yuan Lee, Hsinchu County (TW)

(73) Assignee: Industrial Technology Research Institute, Hsinchu (TW)

(21) Appl. No.: 16/846,427

(22) Filed: Apr. 13, 2020

Related U.S. Application Data
(60) Provisional application No. 62/870,061, filed on Jul. 3, 2019.

(30) Foreign Application Priority Data
Dec. 2, 2019 (TW) 108143959

(51) Int. Cl. G06N 3/08; G11C 11/54; G06N 3/04

(52) U.S. Cl. CPC G06N 3/08; G06N 3/04; G11C 11/54

(57) ABSTRACT

A neural circuit is provided. The neural circuit includes a neural array. The neural array includes a plurality of semiconductor components. Each of the semiconductor components stores a weighting value to generate a corresponding output current or a corresponding equivalent resistance. The neural array receives a plurality of input signals to control the semiconductor components in the neural array and respectively generates the output currents or changes the equivalent resistances. Since the semiconductor components are coupled to each other, output of the neural array may generate a summation current or a summation equivalent resistance related to the input signals and a weighting condition, so that a computing result exhibits high performance.

### CROSS-REFERENCE TO RELATED APPLICATION

This application claims the priority benefits of U.S. provisional application Ser. No. 62/870,061, filed on Jul. 3, 2019, and Taiwan application serial no. 108143959, filed on Dec. 2, 2019. The entirety of each of the above-mentioned patent applications is hereby incorporated by reference herein and made a part of this specification.

### BACKGROUND

### Technical Field

The disclosure relates to a circuit, and more particularly, relates to a neural circuit.

### Background

Nowadays, artificial intelligence (AI) is widely applied to different technical fields to provide applications such as identification, warning, and operation assistance in daily life. Nevertheless, due to fast development of AI and emergence of various new network types, the demand for high hardware performance continues to grow. In response to the development of AI, development of AI computing hardware featuring high performance becomes the main goal.

Further, the computing hardware for achieving AI may be mainly implemented through the Von Neumann structure. In such structure, the weighting values are stored mainly through the memory, and the input signal is processed and the weighting values of the memory are accessed through the processing unit to generate a computing result, and neural computing is thereby performed. Nevertheless, since the processing unit needs to access the weighting information stored in the memory when the processing unit performs computing, power is considerably consumed and computing delay is generated. The Von Neumann bottleneck thus occurs in the Von Neumann structure, power consumption and computing performance of the neural hardware are thus limited.

### SUMMARY

The disclosure provides a neural circuit capable of providing improved power consumption and computing speed performed by the neural circuit.

A neural circuit includes a neural array. The neural array includes a plurality of semiconductor components. Each of the semiconductor components stores a weighting value to generate a corresponding output current or a corresponding equivalent resistance. The neural array receives a plurality of input signals to control the semiconductor components in the neural array and respectively generates the output currents or changes the equivalent resistances. Since the semiconductor components are coupled to each other, output of the neural array may generate a summation current or a summation equivalent resistance related to the input signals and a weighting condition, so that the computing result achieves high performance.

Therefore, in the neural circuit provided by the disclosure, since the weighting values are not required to be stored through an additional storage device, the corresponding weighting values may be stored through the semiconductor components in the neural circuit provided by the disclosure. As such, disadvantages related to computing power and computing delay in the prior art are thereby improved when the weighting values are accessed, and the manufacturing costs are also effectively lowered.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic diagram of a neural array according to an exemplary embodiment of the disclosure.

FIG. 2 is a schematic diagram of another neural array according to an exemplary embodiment of the disclosure.

FIG. 3 is a schematic diagram of another neural array according to an exemplary embodiment of the disclosure.

FIG. 4 is a schematic diagram of another neural array according to an exemplary embodiment of the disclosure.

FIG. 5 is a schematic diagram of another neural array according to an exemplary embodiment of the disclosure.

FIG. 6 is a schematic diagram of another neural array according to an exemplary embodiment of the disclosure.

FIG. 7 is a schematic diagram of another neural array according to an exemplary embodiment of the disclosure.

FIG. 8 is a partial layout diagram of another neural array according to an exemplary embodiment of the disclosure.

FIG. 9A is a schematic diagram of another neural array according to an exemplary embodiment of the disclosure.

FIG. 9B, FIGS. 9C, and 9D are examples illustrating connections of different metal layers of a dashed circle shown in FIG. 9A.

FIG. 10 is a schematic diagram of another neural array according to an exemplary embodiment of the disclosure.

FIG. 11 is a schematic equivalent diagram of a computing result generated by a neural array according to an exemplary embodiment of the disclosure.

FIG. 12 is a schematic conceptual diagram of processing of an output signal by a neural array according to an exemplary embodiment of the disclosure.

FIG. 13 is a schematic conceptual diagram of processing of an output signal by a neural array according to an exemplary embodiment of the disclosure.

FIG. 14 is a schematic conceptual diagram of processing of an output signal by a neural array according to an exemplary embodiment of the disclosure.

### DETAILED DESCRIPTION OF DISCLOSED EMBODIMENTS

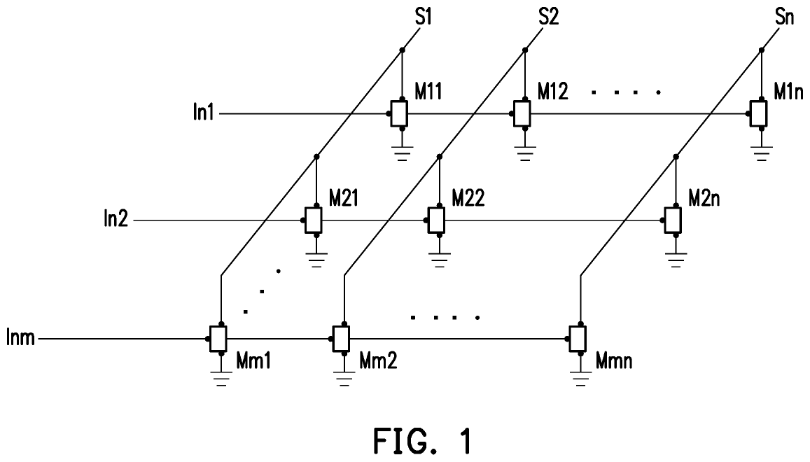

With reference to FIG. 1, FIG. 1 is a schematic diagram of a neural array 1 according to an exemplary embodiment of the disclosure. The neural array 1 includes a plurality of semiconductor components M11 to Mmn. Each of the semiconductor components has a corresponding weighting value, so as to generate a corresponding output current or equivalent resistance when being enabled or turned on. In this embodiment, the semiconductor components M11 to Mmn may be divided into n columns and m rows. The semiconductor components of each column (e.g., the semiconductor components M11, M21 to Mm1, M12, M22 to Mm2, . . . , etc.) may be divided into a same neural sub-group (in the following part of the specification, M11 and M21 to Mm1 are called as a first neural sub-group, M12 and M22 to Mm2 are called as a second neural sub-group, . . . , etc., and the rest may be deduced by analogy) and are coupled to one output terminal (e.g., one of output terminals S1 to Sn) together. The semiconductor components of each row (e.g., the semiconductor components M11 to M1n, M21 to M2n, . . . , etc.) may together receive one input signal (e.g., one of input signals In1 to Inm) configured to control magnitude of currents or the equivalent resistances of the semiconductor components of such row. Therefore, each of the semiconductor components M11 to Mmn in the neural array 1 may be designed as a neural cell configured to store the corresponding weighting value, so that each of the semiconductor components M11 to Mmn generates the corresponding current or equivalent resistance. The currents of all of the semiconductor components in each of the neural sub-groups flow through the corresponding one of the output terminals S1 to Sn. A computing result corresponding to each of the neural sub-groups may thereby be generated when the currents or voltages of the output terminal are determined. Herein, a number of the columns and a number of the rows of the neural array 1 may be adjusted according to different design needs and are not limited to the content provided by this embodiment. The semiconductor components may be implemented in different manners according to different design concepts and user needs. In an embodiment, the semiconductor components may be metal oxide semiconductor field-effect-transistors (MOSFETs). In an embodiment, the semiconductor components may be bipolar junction transistors (BJTs). In an embodiment, the semiconductor components may be vacuum tubes. In an embodiment, the semiconductor components may be quantum gates. The following content provides exemplary embodiments to describe implementation of the semiconductor components acting as MOSFETs; nevertheless, people having ordinary skill in the art understand that the scope of the disclosure is not limited thereto.

Further, each of the semiconductor components in each of the neural sub-groups has a first terminal, a second terminal, and a control terminal. Each of the semiconductor components stores a corresponding weighting value according to different arrangement relationships and a received signal. In an embodiment, a gate width-to-length ratio in each of the semiconductor components may be adjusted according to the corresponding weighting value of each of the semiconductor components. For instance, the gate width-to-length ratio of each of the semiconductor components may be increased or decreased according to the weighting value required by design, and then the output current or the equivalent resistance of each of the semiconductor components may be further adjusted. In other words, each of the semiconductor components may store the corresponding weighting value according to the configured gate width-to-length ratio, so as to generate the corresponding output current or equivalent resistance. In an embodiment, a threshold voltage of each of the semiconductor components is configured according to the corresponding weighting value. For instance, the threshold voltages of the semiconductor components may be increased or decreased according to the designed weighting values. When voltages of the input signals are identical, although a voltage difference between the control terminal and the second terminal (e.g., a gate or a source) of each of the semiconductor components is unchanged, since the threshold voltage of each of the semiconductor components may be generated according to the corresponding weighting value, each of the semiconductor components generates the corresponding output current or equivalent resistance. In other words, each of the semiconductor components may store the corresponding weighting value according to the configured threshold voltage. In an embodiment, the semiconductor components M11 to Mmn may be manufactured by different manufacturing methods through a low threshold voltage (LVT) or an ultra low threshold voltage (ULVT). Therefore, the voltage differences between the control terminals and the second terminals (e.g., gates and sources) of the semiconductor components may lead to generation of different output currents or equivalent resistances. In this way, in the neural array 1, the weighting values of the semiconductor components may be adjusted according to configured different threshold voltages.

As such, the control terminal (e.g., the gate) of each of the semiconductor components may receive the corresponding one of the input signals In1 to Inm to control the current value or the equivalent resistance generated by each of the semiconductor components. In each of the neural sub-groups, the first terminals (e.g., drains) of the semiconductor components are coupled to one output terminal (e.g., one of the output terminals S1 to Sn) together, and the second terminals (e.g., the sources) of the semiconductor components are coupled to a first reference voltage (e.g., a ground voltage Gnd). Therefore, each of the neural sub-groups may function according to the corresponding one of the input signals In1 to Inm and generates the computing result at the output terminal, for example, the first neural sub-group generates the computing result at the output terminal S1, the second neural sub-group generates the computing result at the output terminal S2, and so on. In this way, a multiply-and-add operation in a neural circuit is achieved. In each of the semiconductor components, details of how the weighting value is stored (for example, the weighting value is stored according to the gate width-to-length ratio, the voltage difference between the gate and the source, the threshold voltage, and the like) so that the corresponding output current or equivalent resistance is generated shall be known to people having ordinary skill in the art, and thereby, such details are not provided herein.

In short, in the neural array 1, the corresponding weighting value is stored through each of the semiconductor components without an additional storage device configured to store the weighting value. As such, disadvantages related to computing power and computing delay in the prior art are thereby improved when the weighting values are accessed, and the manufacturing costs are also effectively lowered.

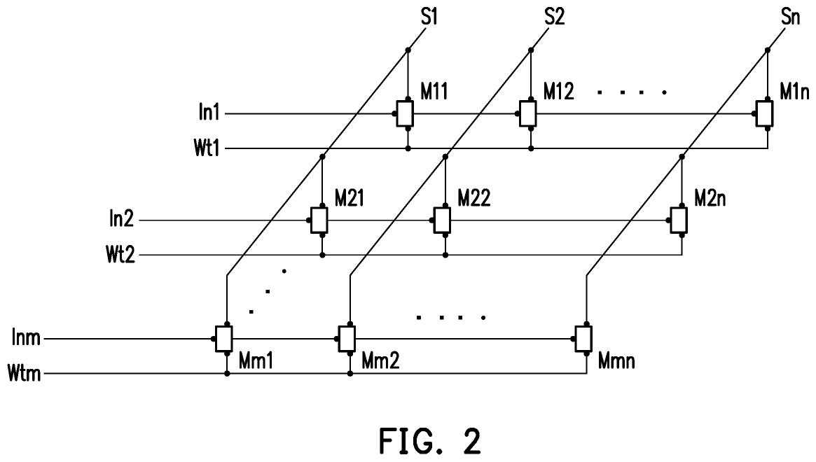

With reference to FIG. 2, FIG. 2 is a schematic diagram of another neural array 2 according to an exemplary embodiment of the disclosure. The neural array 2 is similar to the neural array 1 shown in FIG. 1, so the same reference numerals are used to represent identical elements. The difference between the neural array 2 and the neural array 1 is that the neural array 2 receives a plurality of weighting adjustment signals Wt1 to Wtm respectively transmitted to the second terminals (e.g., the sources) of the semiconductor components of each row. As such, the first terminals (e.g., the drains) of all the semiconductor components of each of the neural sub-groups in the neural array 2 are coupled to the same output terminal. The control terminals (e.g., the gates) of the semiconductor components of each of the neural sub-groups respectively receive the input signal. The second terminals (e.g., the sources) of the semiconductor components of each of the neural sub-groups respectively receive the weighting adjustment signal. In other words, in each of the semiconductor components, the output current or the equivalent resistance is adjusted according to the gate width-to-length ratio and the threshold voltage, and besides, the generated output current or equivalent resistance is adjusted according further to a difference value between the input signal and the weighting adjustment signal received by each of the semiconductor components. The neural sub-groups receive the input signals In1 to Inm and the weighting adjustment signals Wt1 to Wtm and accordingly generate the computing results at the corresponding output terminals.

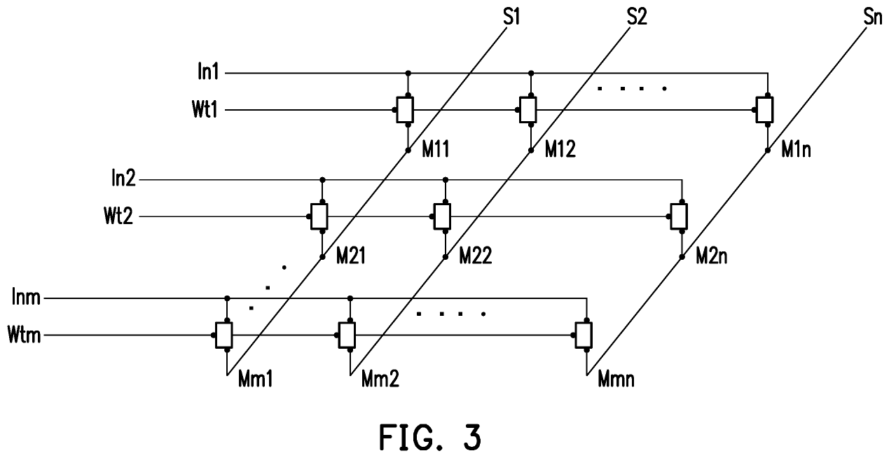

With reference to FIG. 3, FIG. 3 is a schematic diagram of another neural array 3 according to an exemplary embodiment of the disclosure. In the neural array 3, the first terminal (e.g., the drain) of each of the semiconductor components in each of the neural sub-groups receives the corresponding input signal. The gate of each of the semiconductor components in each of the neural sub-groups receives the corresponding weighting adjustment signal. The second terminals (e.g., the sources) of all the semiconductor components in each of the neural sub-groups are coupled to the same output terminal (one of the output terminals S1 to Sn) together. Therefore, in the neural array 3, turning on or off of the semiconductor components may be controlled according to the weighting adjustment signals Wt1 to Wtm, and the output currents or the equivalent resistances generated by the semiconductor components may be adjusted according to the input signals In1 to Inm. In this way, each of the neural sub-groups generates the corresponding computing result on the corresponding output terminal.

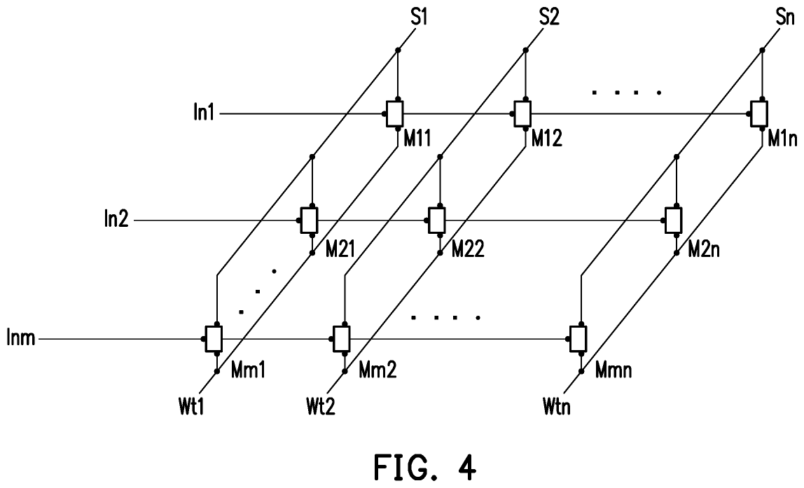

With reference to FIG. 4, FIG. 4 is a schematic diagram of another neural array 4 according to an exemplary embodiment of the disclosure. In the neural array 4, the first terminals (e.g., the drains) of all of the semiconductor components in each of the neural sub-groups are coupled to the same output terminal (one of the output terminals S1 to Sn) together. The control terminal (e.g., the gate) of each of the semiconductor components of each of the neural sub-groups receives the corresponding input signal. The second terminals (e.g., the sources) of all of the semiconductor components in each of the neural sub-groups receive the same weighting adjustment signal, for example, the first neural sub-group receives the weighting adjustment signal Wt1, the second neural sub-group receives the weighting adjustment signal Wt2, and so on. As such, in the neural array 4, turning on or off of the semiconductor components may be respectively controlled according to the input signals In1 to Inm, and the output currents or the equivalent resistances of the neural sub-groups may be adjusted according to the weighting adjustment signals Wt1 to Wtn. In this way, each of the neural sub-groups generates the corresponding computing result on the corresponding output terminal.

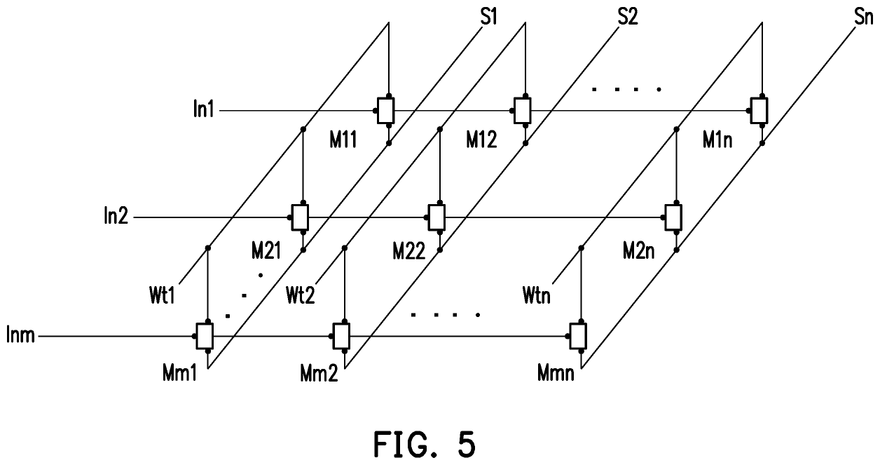

With reference to FIG. 5, FIG. 5 is a schematic diagram of another neural array 5 according to an exemplary embodiment of the disclosure. In the neural array 5, the first terminals (e.g., the drains) of all of the semiconductor components in each of the neural sub-groups receive the same weighting adjustment signal (e.g., one of the weighting adjustment signals Wt1 to Wtn) together. The control terminal (e.g., the gate) of each of the semiconductor components of each of the neural sub-groups receives the corresponding input signal. The second terminals (e.g., the sources) of all the semiconductor components in each of the neural sub-groups are coupled to the same output terminal (one of the output terminals S1 to Sn) together. As such, in the neural array 5, turning on or off of the semiconductor components may be respectively controlled according to the input signals In1 to Inm, and the output currents or the equivalent resistances of the corresponding neural sub-groups may be adjusted according to the weighting adjustment signals Wt1 to Wtn. In this way, each of the neural sub-groups generates the computing result on the corresponding output terminal.

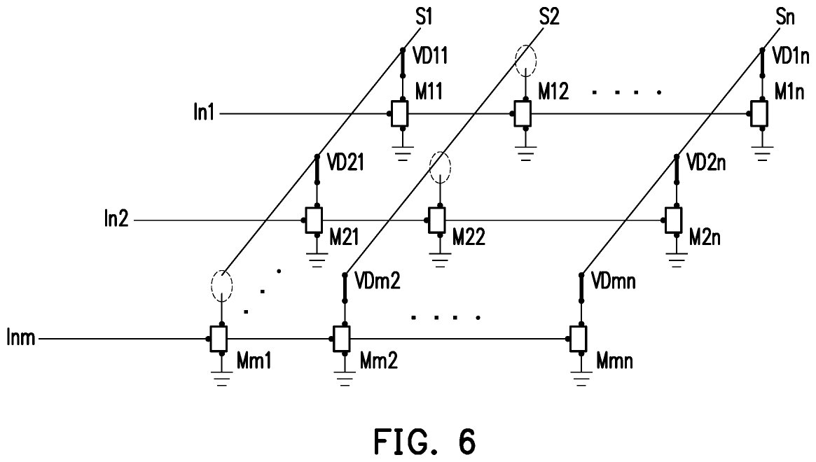

With reference to FIG. 6, FIG. 6 is a schematic diagram of another neural array 6 according to an exemplary embodiment of the disclosure. The neural array 6 is similar to the neural array 1 shown in FIG. 1, so the same reference numerals are used to represent identical elements. In the neural array 6, the first terminals (e.g., the drains) of part of the semiconductor components are connected to or cut off from conductive wires on a metal layer respectively through via plugs, for example, the drains of the semiconductor components M11, M1n, M21, M2n, Mm2, and Mmn are connected to the conductive wires respectively through the via plugs VD11, VD1n, VD21, VD2n, VDm2, and VDmn). When no via plugs are disposed on the first terminals (e.g., the drains) of the semiconductor components, for example, no via plugs are disposed on the drains of the semiconductor components M12, M22, and Mm1, the output currents or the equivalent resistances generated by the semiconductor components cannot be reflected to the output terminals. In other words, in each of the semiconductor components in the neural array 6, the corresponding weighting value of the semiconductor component is adjusted through the via plug on the first terminal (e.g., the drain). For instance, as shown in FIG. 6, no via plug is provided on the dashed circle of the first terminal (e.g., the drain) of the semiconductor component M12, so the weighting value of the semiconductor component M12 may be regarded as being adjusted to zero, and the weighting value of each of the semiconductor components may be further adjusted.

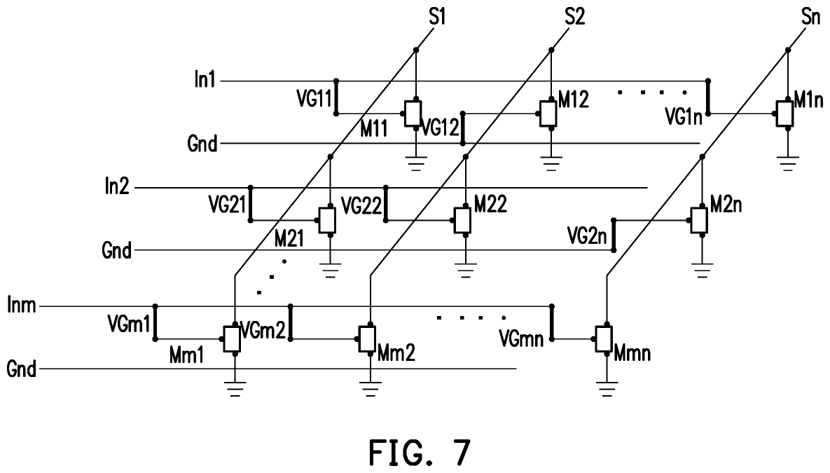

With reference to FIG. 7, FIG. 7 is a schematic diagram of another neural array 7 according to an exemplary embodiment of the disclosure. The neural array 7 is similar to the neural array 1 shown in FIG. 1, so the same reference numerals are used to represent identical elements. In the neural array 7, the control terminals (e.g., the gates) of the semiconductor components receive the input signals or the first reference voltage (e.g., the ground voltage Gnd) respectively through via plugs VG11 to VGmn. For instance, the control terminals (e.g., the gates) of the semiconductor components M11, M1n, M21, M22, Mm1, Mm2, and Mmn may receive the corresponding input signals through the via plugs VG11, VG1n, VG21, VG22, VGm1, VGm2, and VGmn, so that the semiconductor components may accordingly generate the output currents or the equivalent resistances. For instance, the control terminals (e.g., the gates) of the semiconductor components M12 and M2n may receive the first reference voltage (e.g., the ground voltage Gnd) through the via plugs VG12 and VG2n. The semiconductor components may generate the corresponding output currents or the equivalent resistances according to arrangement of the via plugs, and that the weighting values of the semiconductor components may be regarded as being adjusted to zero. In other words, in each of the semiconductor components in the neural array 7, the corresponding weighting value of the semiconductor component may be adjusted through the via plug on the control terminal (e.g., the gate).

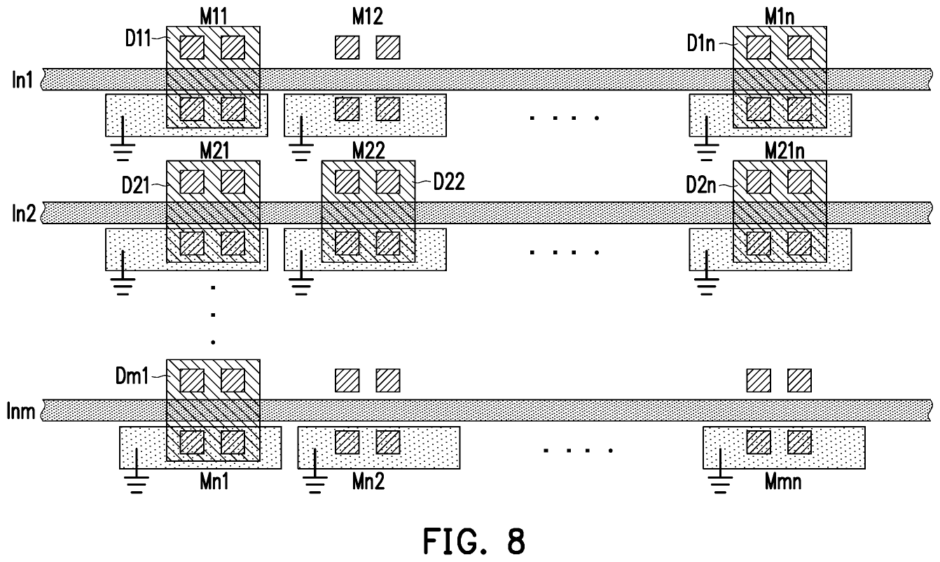

With reference to FIG. 8, FIG. 8 is a partial layout diagram of another neural array 8 according to an exemplary embodiment of the disclosure. Part of a component structure of the neural array 8 (e.g., the coupling relationship between the drain and the source of each of the semiconductor components in each of the neural sub-groups, a trace of the metal layer, etc.) is not depicted for ease of reading. In the neural array 8, in each of the semiconductor components, the weighting value of the semiconductor component is adjusted through a diffusion layer. For instance, the semiconductor components M11, M1n, M21, M22, M2n, and Mm1 respectively include diffusion layers D11, D1n, D21, D22, D2n, and Dm1. As such, these semiconductor components may accordingly generate the corresponding output currents or equivalent resistances for computing. For instance, the semiconductor components M12, Mm2, and Mmn do not include diffusion layers. As such, these semiconductor components do not generate corresponding output currents or equivalent resistances for computing, and the weighting values of these semiconductor components may be regarded as being adjusted to zero. In other words, in the neural array 8, the weighting value of each of the semiconductor components may be adjusted by determining whether the semiconductor component has a diffusion layer.

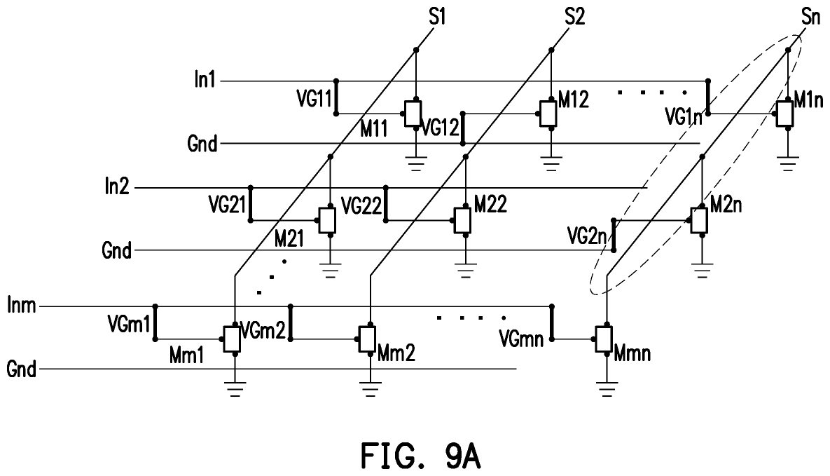

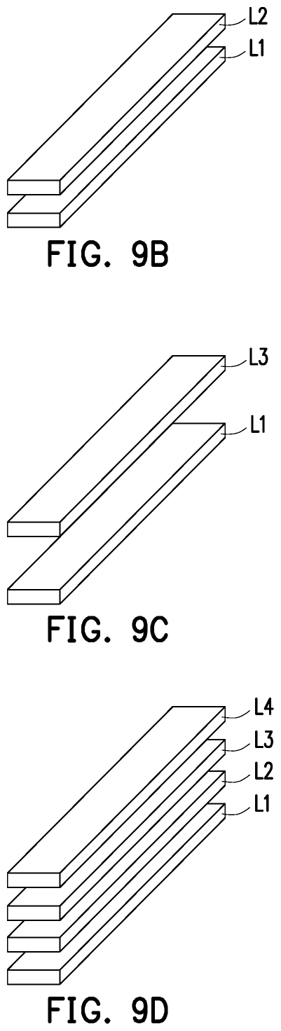

With reference to FIG. 9A, FIG. 9A is a schematic diagram of another neural array 9 according to an exemplary embodiment of the disclosure. The neural array 9 is similar to the neural array 7 shown in FIG. 7, so the same reference numerals are used to represent identical elements. In each of the neural sub-groups in the neural array, the first terminals (e.g., the drains) of all of the semiconductor components are connected to one output terminal (one of the output terminals S1 to Sn) together through one or a plurality of metal layers. For instance, FIG. 9B, FIGS. 9C, and 9D are examples illustrating connections of different metal layers of a dashed (the output terminal Sn) circle shown in FIG. 9A. Generally, a metal layer located at a high position exhibits a great thickness and thereby has a great parasitic capacitance and a less parasitic resistance. Through different arrangements of the connected metal layers, the weighting values of each of the neural sub-groups may be adaptively adjusted. For instance, as shown in FIG. 9B, the semiconductor components M1n to Mmn are connected through metal layers L1 and L2 at the output terminal Sn. As shown in FIG. 9C, the semiconductor components M1n to Mmn are connected through metal layers L1 and L3 at the output terminal Sn. As shown in FIG. 9D, the semiconductor components M1n to Mmn are connected through metal layers L1 to L4 at the output terminal Sn. In an embodiment, 5% to 30% of an overall weighting value of the neural sub-groups may be adjusted through changing the connection manner of the metal layers on the output terminal. In other words, in the illustrations depicted in FIG. 9B to 9D, as different metal layers are connected to the semiconductor components M1n to Mmn at the output terminal Sn, the overall weighting value of the neural sub-groups may be adaptively adjusted according to different design needs, and that the weighting values of the semiconductor components in the neural sub-groups may be accordingly adjusted.

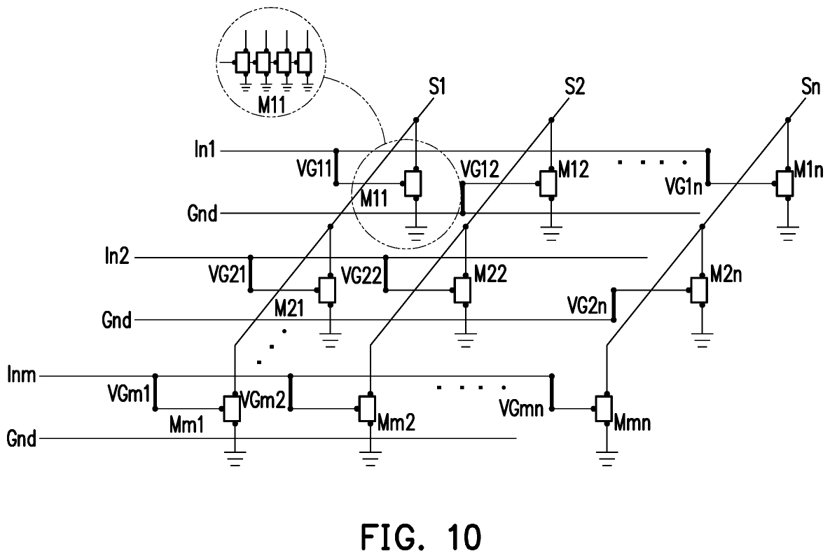

With reference to FIG. 10, FIG. 10 is a schematic diagram of another neural array 10 according to an exemplary embodiment of the disclosure. The neural array 10 is similar to the neural array 7 shown in FIG. 7, so the same reference numerals are used to represent identical elements. The difference between the neural array 10 and the neural array 7 is that the semiconductor components in the neural array 10 include one or more parallel-connected sub-semiconductor elements. For instance, the semiconductor component M11 includes four parallel-connected sub-semiconductor elements. The output current or the equivalent resistance generated by the semiconductor component M11 may thereby be adjusted according to a number of the parallel-connected elements. Therefore, in the neural array 10, the weighting values may be adjusted according to the number of the parallel-connected sub-semiconductor elements included in each of the semiconductor components.

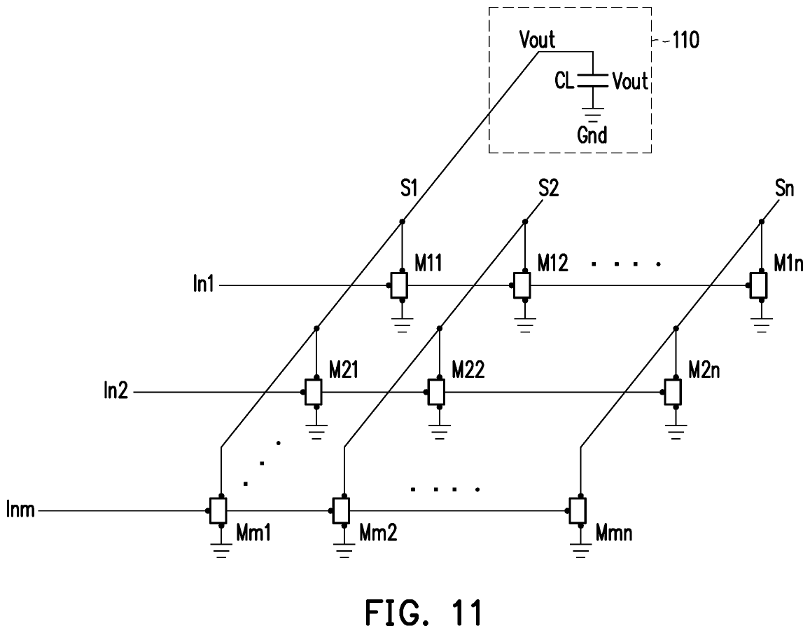

With reference to FIG. 11, FIG. 11 is a schematic equivalent diagram of a computing result generated by a neural array 11 according to an exemplary embodiment of the disclosure. In this embodiment, in the first neural sub-group in the neural array 11, the computing result is generated through determining the voltage on the output terminal S1 through a computing circuit 110. In FIG. 11, although merely a circuit structure of the computing result generated by the first neural sub-group is depicted, computing circuits of other neural sub-groups may be deduced by people having ordinary skill in the art according to the first neural sub-group. Specifically, in this embodiment, the first neural sub-group generates the corresponding output currents or equivalent resistances according to the input signal and the weighting value, charges or discharges a capacitor CL on the output terminal S1, and generates the corresponding computing result. The output terminal S1 is coupled to one terminal of the capacitor CL, and the other terminal of the capacitor CL is coupled to the first reference voltage (e.g., the ground voltage Gnd), so that the corresponding computing result on the output terminal S1 is obtained. The output terminal S1 may be pre-charged to a specific voltage. When the input signals In1 to Inm are inputted to the semiconductor components M11 to Mm1 in the first neural sub-group, the semiconductor components M11 to Mm1 generate the corresponding output currents or equivalent resistances and charge or discharge a voltage across the capacitor CL to generate a corresponding output voltage. In the neural array 11, the weighting values in the neural sub-groups may thereby be determined by measuring changes of an output voltage Vout, so that the computing results of the neural sub-groups are further generated.

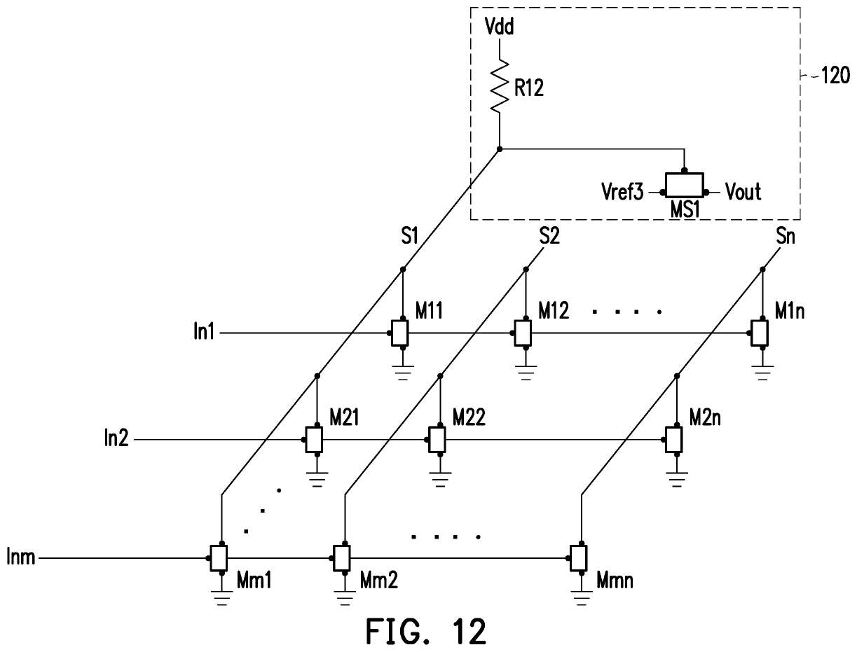

With reference to FIG. 12, FIG. 12 is a schematic conceptual diagram of processing of an output signal generated by a neural array 12 according to an exemplary embodiment of the disclosure. In this embodiment, in a computing circuit 120 of the neural array 12, the semiconductor components are controlled through resistor voltage division to generate the computing result of the first neural sub-group. Specifically, the output terminal S1 is coupled to one terminal of a resistor R12. The other terminal of the resistor R12 receives a second reference voltage (e.g., an operating voltage Vdd), and the output terminal S1 is coupled to the control terminal (e.g., the gate) of the semiconductor component MS1. Therefore, the voltage of the output terminal S1 may be biased according to a ratio of a resistance of the resistor R12 to the equivalent resistances of the semiconductor components M11 to Mm1 connected in parallel in the neural sub-group, and the output current or the equivalent resistance of the semiconductor component MS1 may be accordingly controlled. Therefore, when the voltage on the output terminal S1 is greater than or equal to a predetermined voltage (a difference value between the voltage of the output terminal S1 and a third reference voltage Vref3 is greater than or equal to the threshold voltage of the semiconductor component MS1 in this embodiment), the semiconductor component MS1 is controlled to output the third reference voltage Vref3 as the output voltage Vout. When the voltage on the output terminal S1 is less than the predetermined voltage, the semiconductor component MS1 generates the corresponding output current or equivalent resistance, for example, the output current generated by the semiconductor component MS1 may be close to zero or the equivalent resistance is close to infinity. As such, the computing result of the first neural sub-group may be determined by measuring the output voltage Vout of the computing circuit 120 in the neural array 12.

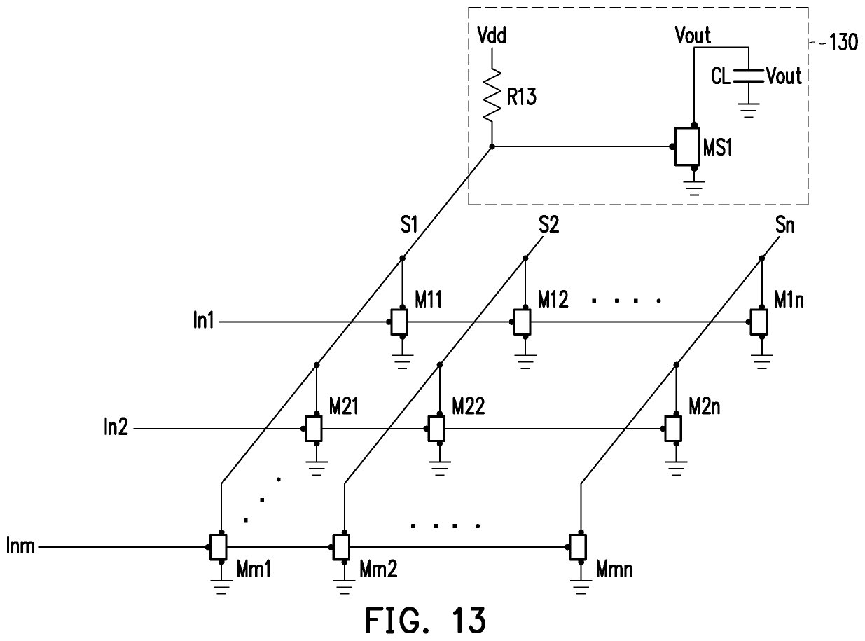

With reference to FIG. 13, FIG. 13 is a schematic conceptual diagram of a neural array 13 generating an output signal according to an exemplary embodiment of the disclosure. The neural array 13 is similar to the neural array 12, so the same reference numerals are used to represent identical elements. The difference between the neural array 13 and the neural array 12 is that one end of the semiconductor component MS1 in a computing circuit 130 is coupled to the capacitor CL, and the other terminal of the semiconductor component MS1 receives the first reference voltage (e.g., the ground voltage Gnd). The other terminal of the capacitor CL receives the first reference voltage (e.g., the ground voltage Gnd). Similar to the neural array 12, the semiconductor component MS1 is controlled through resistor voltage division on the output terminal, and the pre-charged capacitor CL is discharged through the output current or the equivalent resistance outputted by the semiconductor component MS1 in the neural array 13. Therefore, in the neural array 13, the computing results of the neural sub-groups may be generated by measuring voltage changes of the output voltage Vout.

In an embodiment, the gate width-to-length ratio of the semiconductor component MS1 may be adaptively changed, so that the weighting values of the corresponding neural sub-group may be adjusted. For instance, when the gate width-to-length ratio of the semiconductor component MS1 is increased, a discharging capability of driving the capacitor CL is improved, so that the weighting values of the semiconductor components M11 to Mm1 of the entire neural sub-groups are regarded to be increased.

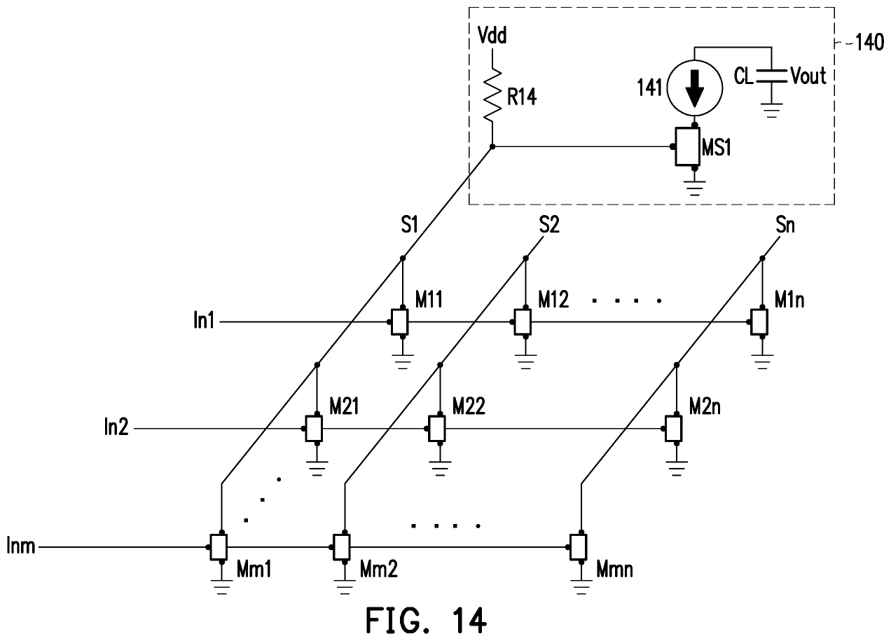

With reference to FIG. 14, FIG. 14 is a schematic conceptual diagram of a neural array 14 generating an output signal according to an exemplary embodiment of the disclosure. The neural array 14 is similar to the neural array 13, so the same reference numerals are used to represent identical elements. The difference between the neural array 14 and the neural array 13 is that a computing circuit 140 additionally includes a current sensor 141 connected in series between the semiconductor component MS1 and the capacitor CL and generates corresponding output according to magnitude of a driving current generated by the semiconductor component MS1. In an embodiment, the current sensor 141 may generate an analog or a digital output signal to be treated as the computing result according to the output current. In an embodiment, the output signal generated by the current sensor 141 may drive a counter, and a number of times the counter is driven by the current sensor 141 is treated as the computing result.

In view of the forgoing, the computing in memory (CIM) may be achieved through the gate width-to-length ratios and the threshold voltages of the semiconductor components in the neural circuit, and the stored weighting values may be further adjusted through different implementations. Disadvantages related to power consumption and computing speed found in the prior art may thereby be effectively overcome.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A neural circuit, comprising:
a neural array, comprising a plurality of semiconductor components, wherein each of the semiconductor components stores a weighting value to generate a corresponding output current, and the semiconductor components are divided into a plurality of neural sub-groups,
wherein the neural sub-groups respectively receive a plurality of input signals to control each of the semiconductor components to generate the output current, and each of the neural sub-groups calculates a sum of the output currents of the semiconductor components through an output terminal to generate a computing result.

2. The neural circuit as claimed in claim 1, wherein the weighting value of each of the semiconductor components corresponds to at least one of a gate width-to-length ratio and a threshold voltage of each of the semiconductor components.

3. The neural circuit as claimed in claim 1, wherein each of the semiconductor components has a first terminal, a second terminal, and a control terminal, the first terminal is coupled to the output terminal, the second terminal is coupled to a first reference voltage, and the control terminal receives one of the input signals.

4. The neural circuit as claimed in claim 1, wherein each of the semiconductor components has a first terminal, a second terminal, and a control terminal, the first terminal is coupled to the output terminal, the second terminal receives a weighting adjustment signal, and the control terminal receives one of the input signals.

5. The neural circuit as claimed in claim 1, wherein each of the semiconductor components has a first terminal, a second terminal, and a control terminal, the first terminal receives one of the input signals, the second terminal is coupled to the output terminal, and the control terminal receives a weighting adjustment signal.

6. The neural circuit as claimed in claim 1, wherein each of the semiconductor components has a first terminal, a second terminal, and a control terminal, the first terminal is coupled to the output terminal, the second terminal receives a weighting adjustment signal, and the control terminal receives one of the input signals.

7. The neural circuit as claimed in claim 1, wherein each of the semiconductor components has a first terminal, a second terminal, and a control terminal, the first terminal receives a weighting adjustment signal, the second terminal is coupled to the output terminal, and the control terminal receives one of the input signals.

8. The neural circuit as claimed in claim 1, wherein each of the semiconductor components comprises a first terminal, and the weighting value of each of the semiconductor components is adjusted through a via plug connected onto the first terminal.

9. The neural circuit as claimed in claim 1, wherein each of the semiconductor components comprises a control terminal, and the weighting value of each of the semiconductor components is adjusted through a via plug connected onto the control terminal.

10. The neural circuit as claimed in claim 1, wherein each of the semiconductor components adjusts the weighting value of each of the semiconductor components through a diffusion layer.

11. The neural circuit as claimed in claim 1, wherein the output terminal has at least one metal layer, and the weighting value of each of the semiconductor components in the neural sub-groups is adjusted through the at least one metal layer.

12. The neural circuit as claimed in claim 1, wherein each of the semiconductor components comprises at least one parallel-connected sub-semiconductor element, and the weighting value of each of the semiconductor components is adjusted through a number of the at least one parallel-connected sub-semiconductor element.
